(19) United States
(12) Patent Application Publication
(10) Pub. No.: US 2026/0282436 A1
(43) Pub. Date: Sep. 17, 2026

(54) SEMICONDUCTOR DEVICE

(71) Applicant: Minebea Power Semiconductor Device Inc., Ibaraki (JP)

(72) Inventors: Haruka SHIMIZU, Tokyo (JP); Takeru SUTO, Tokyo (JP); Yuki TSUJIKAWA, Tokyo (JP)

(21) Appl. No.: 19/110,155

(22) PCT Filed: Apr. 11, 2023
(86) PCT No.: PCT/JP2023/014740

§ 371 Date: Mar. 10, 2025

(30) Foreign Application Priority Data
Sep. 28, 2022 (JP) 2022-154795

(51) Int. Cl. H10D 30/66; H10D 62/10; H10D 62/40; H10D 62/60; H10D 62/832

(52) U.S. Cl. CPC H10D 30/668; H10D 62/124; H10D 62/40; H10D 62/60; H10D 62/8325; H10D 62/103

(57) ABSTRACT

In some examples, a semiconductor device includes: a plurality of trenches having a longitudinal direction in a first direction and a lateral direction in a second direction in plan view, the plurality of trenches being arranged in the second direction; a first source region of a first electroconductive type; a second source region of the first electroconductive type, including a region having a fin structure at least partially partitioned by the plurality of trenches; a channel region of a second electroconductive type and having a fin structure partitioned by the plurality of trenches; a gate insulation film and gate electrodes that are disposed in the trenches; and a JFET region of the first electroconductive type and a body region of the second electroconductive type. The second source region has a shallower depth from a surface than the first source region.

### TECHNICAL FIELD

The present invention relates to a semiconductor device.

### BACKGROUND ART

A trench MOSFET having a vertical channel fin structure has been proposed as a trench type MOSFET.

FIG. 9 is a perspective view schematically illustrating a structure of a trench MOSFET having a conventional vertical channel fin structure. In FIG. 9, illustrations of gate electrodes, a gate insulating film, an interlayer insulating film, source electrodes, and a drain electrode are omitted.

A conventional semiconductor device 1 illustrated in FIG. 9 includes a plurality of trenches 2 having a longitudinal direction in a first direction and a lateral direction in a second direction in plan view, the plurality of trenches 2 being arranged in the second direction. The trench 2 indicated by a dotted line in the cross section in front of FIG. 9 virtually indicates a position corresponding to the trenches 2 in order to describe the positional relationship between other components and the trenches 2.

A source region of a first conductivity type has a fin structure partially partitioned by the plurality of trenches 2. For convenience of description, in FIG. 9, a non-divided portion of the source region is described as a first source region 3 and a divided portion of the source region is described as a second source region 4.

A channel region 5 of a second conductivity type having a fin structure partitioned by the plurality of trenches 2 is formed, in contact with the second source region 4, on a lower surface of the second source region 4. A JFET region 8 of the first conductivity type is formed below the channel region 5. Body regions 9 of the second conductivity type are formed on sides of the JFET region 8. A drift region 10 of the first conductivity type is formed below the JFET region 8. A drain region 11 of the first conductivity type is formed below the drift region 10.

The conventional semiconductor device 1 illustrated in FIG. 9 also has a channel structure in which gate electrodes are embedded in the trenches 2 with gate insulating films, which are formed on side surfaces of the trenches 2, interposed between the trenches 2 and the gate electrodes and a current flows in a depth direction through the side surface of the trenches 2. The gate electrodes embedded in the trenches 2 are connected to each other outside of the trenches 2.

This structure is capable of reducing an on-resistance by reducing trench pitch and increasing channel density.

Patent Literature related to such a technique includes Patent Literature 1. Paragraphs 0048 to 0052, FIG. 3 and 14 to 18 of Patent Literature 1 describe a configuration similar to that of FIG. 9 described above, although names and detailed structures of components are different.

### CITATION LIST

### Patent Literature

Patent Literature 1: Japanese Patent Application Publication No. 2004-207289

### SUMMARY OF INVENTION

### Technical Problem

The conventional semiconductor device 1 illustrated in FIG. 9, however, has a problem that the on-resistance is low owing to the high channel density, but this correspondingly lowers short-circuit tolerance. In addition, the high channel density increases gate capacitance, resulting in slow switching speed.

An object of the present invention is to provide a semiconductor device, which is a trench MOSFET having a vertical channel fin structure, capable of improving short-circuit tolerance and reducing gate capacitance while maintaining high channel density.

### Solution to Problem

In order to solve the problem described above, a semiconductor device according to the present invention, for example, includes: a plurality of trenches having a longitudinal direction in a first direction and a lateral direction in a second direction in plan view, the plurality of trenches being arranged in the second direction; a first source region of a first conductivity type, placed outside the trenches in the first direction; a second source region of the first conductivity type, including a region having a fin structure at least partially partitioned by the plurality of trenches; a channel region of a second conductivity type, the channel region being in contact with the lower surface of the second source region and having a fin structure partitioned by the plurality of trenches; a gate insulating film placed in the trenches; gate electrodes including a region that is at least partially placed in the trenches; a JFET region of the first conductivity type, placed below the channel region; and a body region of the second conductivity type, placed on sides of the JFET region, and a channel current flowing in a vertical direction, in which the second source region has a shallower depth from a surface than the first source region.

### Advantageous Effects of Invention

According to the semiconductor device of the present invention, even in a case where a short circuit occurs and a high voltage is applied between the source and the drain and therefore a saturation current flows through the source and the drain, since the second source region shallower than the first source region has a higher resistance and the resistance increases at a high temperature, potential of the second source region becomes higher than that of the first source region and voltage of the JFET region increases accordingly, and reverse bias of a PN junction between the JFET region and the body region thus increases resulting in further depletion of the JFET region. Therefore, as compared with the case where the depth of the second source region is the same as that of the first source region, the saturation current can be reduced and the short-circuit tolerance is improved.

In addition, the shallow second source region reduces the overlap capacitance between the gate electrodes and the second source region extending in the depth direction of the trench, and therefore enables a reduction in the gate capacitance.

### BRIEF DESCRIPTION OF DRAWINGS

FIG. 1 is a perspective view illustrating a semiconductor device of Example 1.

FIG. 2 is a sectional view taken along line X1-X1′ of FIG. 1 in the semiconductor device of Example 1.

FIG. 3 is a sectional view taken along line X2-X2′ of FIG. 1 in the semiconductor device of Example 1.

FIG. 4 is a sectional view taken along line Y1-Y1′ of FIG. 1 in the semiconductor device of Example 1.

FIG. 5 is a sectional view taken along line X1-X1′ corresponding to FIG. 2 in the semiconductor device of Example 2.

FIG. 6 is a sectional view taken along line X1-X1′ corresponding to FIG. 2 in the semiconductor device of Example 3.

FIG. 7 is an impurity concentration profile with respect to a depth in a Z1-Z1′ direction in FIG. 6 of the semiconductor device of Example 3.

FIG. 8 is a sectional view taken along line X1-X1′ corresponding to FIG. 2 in the semiconductor device of Example 4.

FIG. 9 is a perspective view schematically illustrating a structure of a trench MOSFET having a conventional vertical channel fin structure.

### DESCRIPTION OF EMBODIMENTS

Hereinafter, examples of the present invention will be described with reference to the drawings. In each drawing and example, the same or similar constituent elements are designated by the same reference signs, and the overlapping description will be omitted.

### Example 1

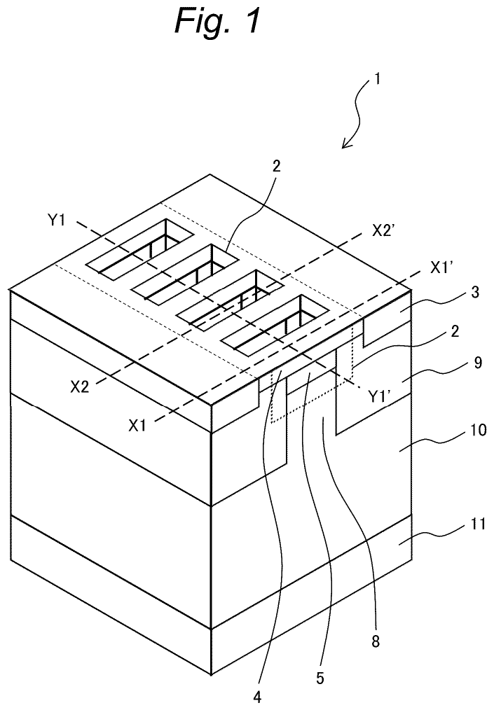

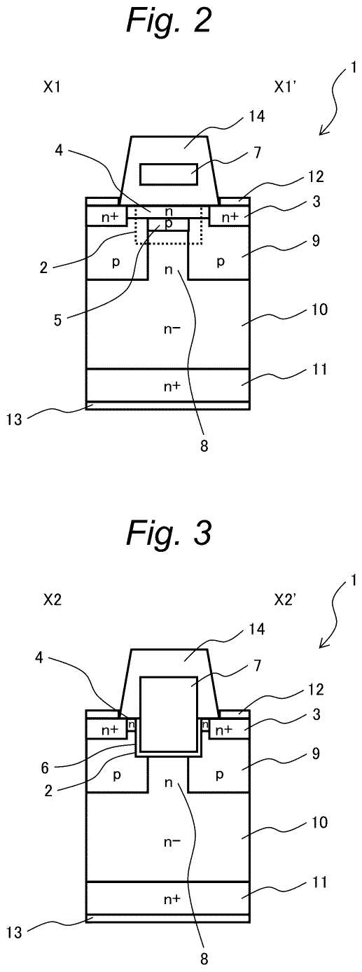

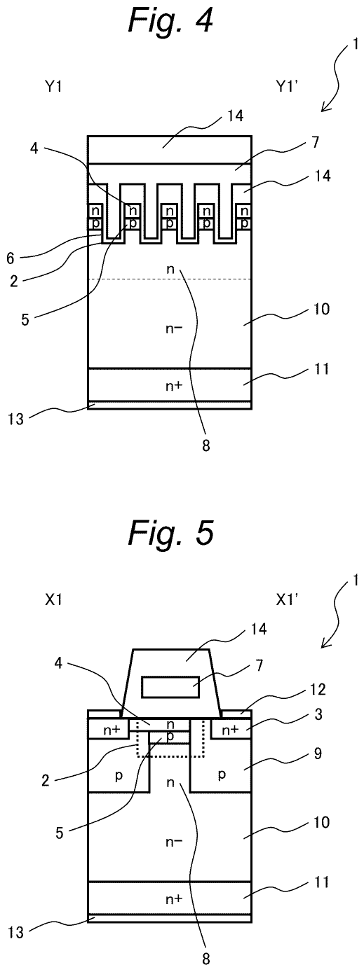

FIG. 1 is a perspective view illustrating a semiconductor device of Example 1, FIG. 2 is a sectional view taken along line X1-X1′ of FIG. 1 in the semiconductor device of Example 1, FIG. 3 is a sectional view taken along line X2-X2′ of FIG. 1 in the semiconductor device of Example 1, and FIG. 4 is a sectional view taken along line Y1-Y1′ of FIG. 1 in the semiconductor device of Example 1. In FIG. 1, illustrations of gate electrodes 7, a gate insulating film 6, an interlayer insulating film 14, source electrodes 12, and a drain electrode 13 are omitted.

A semiconductor device 1 of Example 1 includes, as illustrated in FIG. 1, a plurality of trenches 2 having a longitudinal direction in a first direction and a lateral direction in a second direction in plan view, the plurality of trenches being arranged in the second direction.

The semiconductor device 1 also includes, a first source region 3 of a first conductivity type (n-type in FIG. 2), placed outside the trench 2 in the first direction, a second source region 4 of the first conductivity type, including a region having a fin structure at least partially partitioned by the plurality of trenches 2, and a channel region 5 of a second conductivity type (p-type in FIG. 2) of the fin structure in contact with a lower surface of the second source region 4 and partitioned by the plurality of trenches 2.

Example 1 describes an example in which the first conductivity type is an n-type and the second conductivity type is a p-type; however, the conductivity types are not limited thereto, and the first conductivity type may be the p-type and the second conductivity type may be the n-type. In addition, the trench 2 indicated by a dotted line in the cross section of FIGS. 1 and 2 virtually indicates a position corresponding to the trenches 2 in order to describe the positional relationship between other components and the trenches 2.

The semiconductor device 1 of Example 1 is different from the conventional structure of FIG. 9 in that the second source region 4 has a lower impurity concentration than the first source region 3 and a shallower depth from a surface than the first source region 3, as illustrated in FIG. 2. Example 1 illustrates an example in which the first source region 3 is an n+ (n plus) type having a high concentration, the second source region 4 is an n-type having a lower concentration, and the channel region 5 is a p-type. However, the regions may be of any type that enables achievement of operation intended in Example 1.

Example 1 illustrates an example in which a part of the second source region 4 has a fin structure and the other portion of the second source region 4 is connected to the first source region 3. However, the structure of the second source region 4 is not limited thereto and the entire second source region 4 may have a fin structure.

The semiconductor device 1 also includes, as illustrated in FIGS. 3 and 4, a gate insulating film 6 placed in the trench 2 and gate electrodes 7 including a region that is at least partially placed in the trench 2. For example, as illustrated in FIG. 4, the gate electrodes 7 placed in the trenches 2 are connected to each other outside of the trenches 2. An interlayer insulating film 14 is formed between the portion of the gate electrodes 7 connected to each other and the second source region 4. The interlayer insulating film 14 is formed so as to also cover upper and side portions of the connected portion of the gate electrodes 7. The gate electrodes 7 may be formed of, for example, polysilicon.

The semiconductor device 1 further includes, as illustrated in FIG. 2, a JFET region 8 of the first conductivity type, placed below the channel region 5, body regions 9 of the second conductivity type, placed on sides of the JFET region 8, a drift region 10 of the first conductivity type, placed below the JFET region 8, a drain region 11 of the first conductivity type, placed below the drift region 10, source electrodes 12 connected to upper surface side of the first source regions 3, and a drain electrode 13 connected to a lower surface side of the drain region 11. The channel region 5 is electrically connected to the body regions 9. The JFET region 8 is electrically connected to the drift region 10. The trench 2 is formed so that its longitudinal length overlaps the body regions 9 on both sides sandwiching the JFET region 8, as shown in FIG. 2. A depth of the trench 2 is shallower than the body region 9 and deeper than the channel region 5.

Example 1 illustrates an example in which the JFET region 8 is an n-type, the body region 9 is a p-type, the drift region 10 is a low-concentration n− (n minus) type, and the drain region 11 is a high-concentration n+ (n plus) type. However, the regions may be of any type that enables achievement of operation intended in Example 1. For example, the JFET region 8 may be a low-concentration n− (n minus) type.

In the semiconductor device 1 of Example 1, a gate drive signal is input to the gate electrodes 7 in the trench 2 for control, so that a channel current flows in the channel region 5 of the fin structure in a vertical direction. That is, the trench MOSFET has a vertical channel fin structure. The channel density can thus be increased by reducing the trench pitch to increase the density of the trench 2, so that a channel resistance can be reduced and the on-resistance can be reduced.

Even in a case where a short circuit occurs and a high voltage is applied between the source and the drain and therefore a saturation current flows through the source and the drain, the semiconductor device 1 of Example 1 is capable of reducing the saturation current by pinch-offs, which depletes the JFET region 8 at the time of the short circuit owing to the deep body region 9 and extends the depletion layer from the right and the left to connect to each other. Further, since the second source region 4 shallower than the first source region 3 has a higher resistance and the resistance increases at a high temperature such as when a short circuit occurs, potential of the second source region 4 becomes higher than that of the first source region 3 and voltage of the JFET region 8 increases accordingly, and reverse bias of a PN junction between the JFET region 8 and the body region 9 thus increases, resulting in depletion of the JFET region 8. Therefore, as compared with the case where the depth of the second source region 4 is the same as that of the first source region 3 as in FIG. 9, the saturation current can be reduced and the short-circuit tolerance is improved.

As described in Example 1, the impurity concentration of the second source region 4 is desirably lower than the impurity concentration of the first source region 3. This further increases the resistance, and therefore greater advantageous effect can be achieved. However, note that the impurity concentration of the second source region 4 is not limited thereto and may be the same as the impurity concentration of the first source region 3.

In addition, the shallow second source region 4 reduces the overlap capacitance between the gate electrodes 7 and the second source region 4 extending in the depth direction of the trench 2, and therefore enables a reduction in the gate capacitance. As a result, the switching speed can also be increased.

The trench MOSFET having the vertical channel fin structure typically has a trade-off relationship that when the channel density is high, an on-resistance is low while the short-circuit tolerance is low, the gate capacitance is large, and the switching speed is slow. However, the semiconductor device 1 of Example 1 is capable of improving the short-circuit tolerance and reducing the gate capacitance while maintaining the high channel density, as well as increasing the switching speed.

To sufficiently achieve the advantageous effect of improving the short-circuit tolerance, a sheet resistance of the second source region 4 is desirably 10 times or more a sheet resistance of the first source region 3.

The semiconductor device 1 of Example 1 may be formed of, for example, an n+ (n plus) type SiC substrate; however, the type of substrate is not limited thereto. In addition, the semiconductor device 1 can be manufactured by a widely used manufacturing method, including steps such as forming the n+ (n plus) type drain region 11 using the n+ (n plus) type SiC substrate and forming the n− (n minus) drift region 10 by epitaxial growth, and thus detailed description will be omitted.

### Example 2

FIG. 5 is a sectional view taken along line X1-X1′ corresponding to FIG. 2 in the semiconductor device of Example 2.

Example 2 is a modification of Example 1 and is different from Example 1 in that a connection structure between the second source region 4 and the first source region 3 is different. Other than this connection structure, the present example is substantially the same as Example 1, and thus the following explanation will be focused on features different from each other and the overlapping description will be omitted.

In the semiconductor device 1 of Example 2, as illustrated in FIG. 5, only one end of the second source region 4 is connected to the first source region 3. Although FIG. 5 illustrates an example in which the left end of the second source region 4 is connected to the first source region 3, the connection may be reversed. Alternatively, the end connected may change depending on the location, and there may be both a structure that connects the left end of the second source region 4 and a structure that connects the right end of the second source region 4.

In this way, a larger resistance can be provided by reducing connections, so that the short-circuit tolerance is further improved.

Alternatively, frequency of the reduction may be adjusted in a chip surface. For example, the frequency of reduction may be increased in a place where a high temperature is likely to occur at the time of short circuit to reduce an amount of heat generation.

In this case, it is sufficient if the second source region 4 includes two types of connection structure including a first connection structure in which both ends of the second source region 4 are connected to the first source region 3, as illustrated in FIG. 2, and a second connection structure in which only one end of the second source region 4 is connected to the first source region 3, as illustrated in FIG. 5.

### Example 3

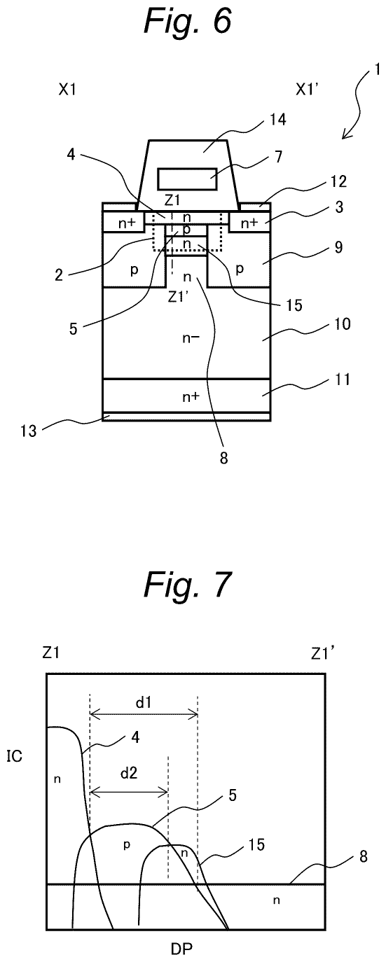

FIG. 6 is a sectional view taken along line X1-X1′ corresponding to FIG. 2 in the semiconductor device of Example 3.

Example 3 is a modification of Example 1 and is different from Example 1 in that an implantation region 15 is provided. Other than the implantation region 15, the present example is substantially the same as Example 1, and thus the following explanation will be focused on features different from each other and the overlapping description will be omitted. Example 3 may be applied to Example 2.

The semiconductor device 1 according to the Example 3 includes, between the channel region 5 and the JFET region 8, the implantation region 15 of the first conductivity type having a higher impurity concentration than the JFET region 8. The implantation region 15 is illustrated as an n-type in FIG. 6; however, the implantation region 15 may be of any type that enables achievement of operation intended in Example 3.

FIG. 7 is an impurity concentration profile with respect to a depth in a Z1-Z1′ direction in FIG. 6 of the semiconductor device of Example 3. A vertical axis represents an impurity concentration IC and a horizontal axis represents a depth DP.

In a case where the channel region 5 is formed by ion implantation, for example, the profile of aluminum which is a p-type dopant is likely to trail, which deepens the channel region 5 than necessary. This also requires to increase the depth of the trench 2, which increases the gate capacitance and shortens the effective length of the JFET region 8, and therefore the short-circuit tolerance is lowered.

Thus, for example, by using nitrogen as an ion specie of the implantation region 15 and placing the implantation region 15 of the first conductivity type between the channel region 5 and the JFET region 8, the implantation region 15 having an impurity concentration higher than the JFET region 8, a channel region depth d1 in the case without the implantation region can be reduced to a channel region depth d2 in the case with the implantation region, and the low concentration region (the tail region) of the channel region 5 can thus be reduced. The depth of the channel region 5 can therefore be reduced while a necessary charge amount is maintained. This enables reduction of the gate capacitance as well as increase of a dimension in a depth direction of the JFET region 8, and therefore also enables improvement of the short-circuit tolerance.

### Example 4

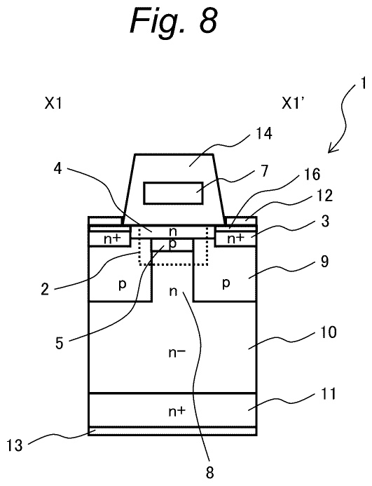

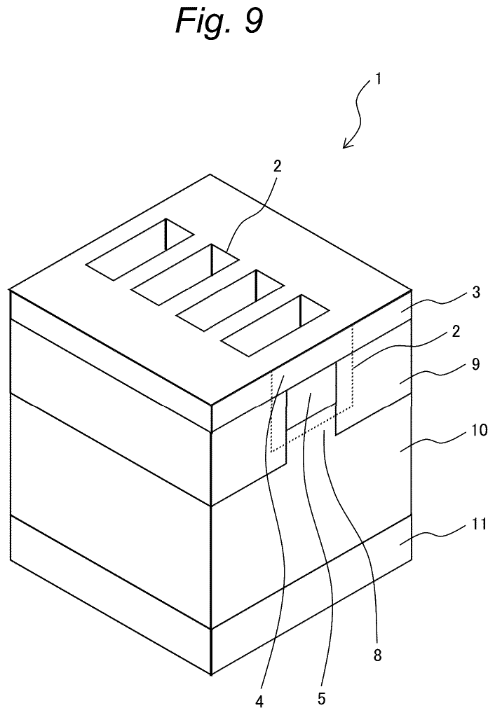

FIG. 8 is a sectional view taken along line X1-X1′ corresponding to FIG. 2 in the semiconductor device of Example 4.

Example 4 is a modification of Example 1 and is different from Example 1 in that a 3C-SiC region 16 is provided. Other than this, the present example is substantially the same as Example 1, and thus the following explanation will be focused on features different from each other and the overlapping description will be omitted. Example 4 may be applied to Example 2 or Example 3.

In the semiconductor device 1 of Example 4, the first source region 3 includes the 3C-SiC region 16 provided on an outermost surface of a 4H-SiC region.

SiC widely used for a power device is a polytype called 4H-SiC. 4H-SiC has a wide band gap and is suitable for high withstand voltage while it is difficult to achieve ohmic contact with and typically requires heat treatment at 900° C. or more. On the other hand, 3C-SiC has a small band gap, so that ohmic contact can be achieved at low temperature. A 3C-SiC surface can be obtained from a 4H-SiC surface by implanting ions having a large mass, such as phosphorus, at a high dose and recrystallizing. Placement of the phosphorus high-dose injection layer in the vicinity of the channel region 5 deteriorates channel characteristics. Meanwhile, in the present example, the second source region 4 is placed in the vicinity of the channel region 5 and the first source region 3 and the channel region 5 are not in contact with each other, and therefore enables application of low-temperature ohmic contact using 3C-SiC. Application of the low-temperature ohmic contact can avoid deterioration of an oxide film in a high-temperature process, which also improves reliability of the oxide film, and therefore the short-circuit tolerance can also be improved.

Although the examples of the present invention have been described above, the present invention is not limited to the configurations described in the examples, and various modifications are possible within the scope of the technical concept of the present invention. In addition, some or all of the configurations described in each example may be applied in combination.

### REFERENCE SIGNS LIST

1 Semiconductor device
2 Trench
3 First source region

4 Second source region
5 Channel region
6 Gate insulating film
7 Gate electrode
8 JFET region
9 Body region
10 Drift region
11 Drain region
12 Source electrode
13 Drain electrode
14 Interlayer insulating film
15 Implantation region
16 3C-SiC region
IC Impurity concentration
DP Depth
d1 Channel region depth without implantation region
d2 Channel region depth with implantation region

1. A semiconductor device comprising:
a plurality of trenches having a longitudinal direction in a first direction and a lateral direction in a second direction in plan view, the plurality of trenches being arranged in the second direction;
a first source region of a first conductivity type, placed outside the trenches in the first direction;
a second source region of the first conductivity type, including a region having a fin structure at least partially partitioned by the plurality of trenches;
a channel region of a second conductivity type, the channel region being in contact with the lower surface of the second source region and having a fin structure partitioned by the plurality of trenches;
a gate insulating film placed in the trenches;
gate electrodes including a region that is at least partially placed in the trenches;
a JFET region of the first conductivity type, placed below the channel region; and
a body region of the second conductivity type, placed on sides of the JFET region, and
a channel current flowing in a vertical direction, wherein
the second source region has a shallower depth from a surface than the first source region.

2. The semiconductor device according to claim 1, wherein
the second source region has a lower impurity concentration than the first source region.

3. The semiconductor device according to claim 1, comprising:
a drift region of the first conductivity type, placed below the JFET region; and
a drain region of the first conductivity type, placed below the drift region.

4. The semiconductor device according to claim 1, comprising:
the gate electrodes placed in the trenches are connected to each other outside of the trenches.

5. The semiconductor device according to claim 1, comprising:
a sheet resistance of the second source region is 10 times or more a sheet resistance of the first source region.

6. The semiconductor device according to claim 1, comprising:
only one end of the second source region is connected to the first source region.

7. The semiconductor device according to claim 1, comprising:
the second source region includes two types of connection structure including: a first connection structure in which both ends of the second source region are connected to the first source region; and a second connection structure in which only one end of the second source region is connected to the first source region.

8. The semiconductor device according to claim 1, comprising:
an implantation region of the first conductivity type, the implantation region having a higher impurity concentration than the JFET region and being placed between the channel region and the JFET region.

9. The semiconductor device according to claim 1, comprising:
the first source region includes a 3C-SiC region provided on an outermost surface of a 4H-SiC region.

10. The semiconductor device according to claim 1, comprising:
the first conductivity type is an n-type and the second conductivity type is a p-type.
